(19) United States
(12) Patent Application Publication
(10) Pub. No.: US 2022/0069030 A1
(43) Pub. Date: Mar. 3, 2022

(54) DISPLAY SUBSTRATE, DISPLAY PANEL AND DISPLAY APPARATUS

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN)

(72) Inventor: Minghung HSU, Beijing (CN)

(21) Appl. No.: 17/419,944

(22) PCT Filed: Sep. 30, 2020
(86) PCT No.: PCT/CN2020/119278

§ 371 Date: Jun. 30, 2021

(30) Foreign Application Priority Data
Sep. 30, 2019 (CN) 201910944276.8

(51) Int. Cl. H01L 27/32

(52) U.S. Cl. CPC H01L 27/3218; H01L 27/3216

(57) ABSTRACT

A display substrate has a plurality of pixel regions. The display substrate includes a base, an accommodating layer disposed on the base, an electrical connection structure disposed on the base, and a light-emitting layer disposed in each depression. The accommodating layer is provided with a contact hole and a plurality of depressions that are located in a pixel region, the plurality of depressions are located on a periphery of the contact hole, and each depression is spaced apart from the contact hole. In a direction perpendicular to the base, the plurality of depressions and the contact hole penetrate the accommodating layer. A portion of the electrical connection structure passes through the contact hole.

### CROSS-REFERENCE TO RELATED APPLICATIONS

This application is a national phase entry under 35 USC 371 of International Patent Application No. PCT/CN2020/119278 filed on Sep. 30, 2020, which claims priority to Chinese Patent Application No. 201910944276.8, filed on Sep. 30, 2019, which are incorporated herein by reference in their entirety.

### TECHNICAL FIELD

The present disclosure relates to the field of display technologies, and in particular, to a display substrate, a display panel and a display apparatus.

### BACKGROUND

The fabrication of printed organic light-emitting diode (Printed OLED) display panels does not require the use of fine metal masks (FMMs) or other patterning processes, and has gradually become one of the mainstream technologies applied to large-sized display panels due to its characteristics such as high material utilization, high efficiency, easy large-area fabrication and full color display, so as to attract widespread attention.

### SUMMARY

In an aspect, a display substrate is provided, which has a plurality of pixel regions. The display substrate includes a base, an accommodating layer disposed on the base, an electrical connection structure disposed on the base, and a light-emitting layer disposed in each depression. The accommodating layer is provided with a contact hole and a plurality of depressions that are located in a pixel region, the plurality of depressions are located on a periphery of the contact hole, and each depression is spaced apart from the contact hole. In a direction perpendicular to the base, the plurality of depressions and the contact hole penetrate the accommodating layer. A part of the electrical connection structure passes through the contact hole.

In position points of a side of an orthogonal projection of the contact hole on the base, a position point with a shortest distance from a wall of at least one depression located on the periphery of the contact hole is a first position point; an orthogonal projection of the contact hole on the base and orthogonal projections of the plurality of depressions on the base are in a shape of polygon or approximate polygon, the first position point is not located at a corner of the polygonal or the approximate polygonal orthogonal projection of the contact hole on the base, and a side of the orthogonal projection of the contact hole on the base closest to the depression is not parallel to at least one side of the orthogonal projection of the depression on the base proximate to the contact hole.

In some embodiments, a side of the orthogonal projection of the contact hole on the base is directly opposite to a corner of an orthogonal projection of a depression located on the periphery of the contact hole on the base, and the first position point is located on this side.

In some embodiments, corners of the orthogonal projection of the depression on the base are rounded corners. In orthogonal projections of the contact hole and the depression directly opposite to the contact hole on the base, a tangent line at a bisecting point of a rounded corner, directly opposite to the contact hole, of the depression is parallel to a side, directly opposite to the depression, of the contact hole.

In some embodiments, in the pixel region, and in orthogonal projections of the contact hole and the plurality of depressions on the base, sides of the contact hole are directly opposite to corners of the plurality of depressions located on the periphery of the contact hole.

In some embodiments, the orthogonal projection of the contact hole on the base is in the shape of rectangle. Four depressions are disposed in the pixel region, and four sides of the rectangular orthogonal projection of the contact hole are directly opposite to corners of the four depressions located on the periphery of the contact hole. Or, three depressions are disposed in the pixel region, and three of the four sides of the rectangular orthogonal projection of the contact hole are directly opposite to corners of the three depressions located on the periphery of the contact hole.

In some embodiments, four depressions are disposed in the pixel region. Light-emitting layers disposed in two depressions are light-emitting layers capable of emitting blue light, and light-emitting layers disposed in remaining two depressions are a light-emitting layer capable of emitting red light and a light-emitting layer capable of emitting green light.

In some embodiments, the contact hole is located at a center position of a rectangle formed by connecting centers of the four depressions in sequence.

In some embodiments, areas of orthogonal projections of the four depressions on the base are same.

In some embodiments, three depressions are disposed in the pixel region. One of the depressions is a first depression, a light-emitting layer disposed in the first depression is a light-emitting layer capable of emitting blue light, and remaining two depressions are second depressions, and light-emitting layers disposed in the two second depressions are a light-emitting layer capable of emitting red light and a light-emitting layer capable of emitting green light. An area of an orthogonal projection of the first depression on the base is greater than an area of an orthogonal projection of each second depression on the base.

In some embodiments, the three depressions are disposed around the contact hole.

In some embodiments, a ratio of the area of the orthogonal projection of the first depression on the base to the area of the orthogonal projection of each second depression on the base is greater than or equal to 1.5, and less than or equal to 6.

In some embodiments, the electrical connection structure includes at least one auxiliary electrode disposed between the base and the accommodating layer, and a cathode layer disposed on a side of the accommodating layer and the light-emitting layer away from the base. The at least one auxiliary electrode is located on a side of the contact hole proximate to the base, and at least one portion of the cathode layer is located in the contact hole, so that the cathode layer and the at least one auxiliary electrode are electrically connected through the contact hole.

In some embodiments, the display substrate further includes an anode disposed between the base and each light-emitting layer, and a pixel circuit disposed between the anode and the base. The pixel circuit is electrically connected to the anode.

In another aspect, a display panel is provided, which includes the display substrate described in the above embodiments, and a photoresist cover plate stacked with the display substrate. The photoresist cover plate includes a plurality of color filter photoresists, and each color filter photoresist is opposite to one depression of the display substrate.

In some embodiments, in the plurality of depressions in each pixel region of the display substrate, light-emitting layers disposed in at least two depressions are light-emitting layers capable of emitting blue light. Color filter photoresists in the photoresist cover plate opposite to the light-emitting layers capable of emitting blue light are blue photoresists, and blue light that is transmitted by the blue photoresists corresponding to different light-emitting layers capable of emitting the blue light in a same pixel region have different wavelength ranges, or have different spectrums peaks.

In another aspect, a display apparatus is provided, which includes the display panel described in the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings.

In addition, the accompanying drawings to be described below may be regarded as schematic diagrams, but are not limitations on an actual size of a product, an actual process of a method and an actual timing of a signal involved in the embodiments of the present disclosure.

FIG. 1 is a top view of a display substrate, in accordance with the related art;

FIG. 2 is a top view of a display substrate, in accordance with some embodiments of the present disclosure;

FIG. 3 is a cross-sectional view taken along a section line O-O′ in FIG. 2;

FIG. 4 is a partial enlarged view of a pixel region of the display substrate in FIG. 2;

FIG. 5 is a top view of a pixel region of a display substrate, in accordance with the related art;

FIG. 6 is a top view of another display substrate, in accordance with some embodiments of the present disclosure;

FIG. 7 is a partial enlarged view of a pixel region of the display substrate in FIG. 6;

FIG. 8 is a pixel distribution diagram of a display substrate, in accordance with some embodiments of the present disclosure;

FIG. 9 is a top view of another display substrate, in accordance with some embodiments of the present disclosure;

FIG. 10 is a structural diagram of a display panel, in accordance with some embodiments of the present disclosure; and

FIG. 11 is a structural diagram of a display apparatus, in accordance with some embodiments of the present disclosure.

### DETAILED DESCRIPTION

Technical solutions in some embodiments of the present disclosure will be described clearly and completely with reference to the accompanying drawings.

Obviously, the described embodiments are merely some but not all embodiments of the present disclosure. All other embodiments obtained on a basis of the embodiments of the present disclosure by a person of ordinary skill in the art shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, and “specific example” or “some examples” are intended to indicate that specific features, structures, materials or characteristics related to the embodiment(s) or example(s) are included in at least one embodiment or example of the present disclosure.

Schematic representations of the above terms do not necessarily refer to the same embodiment(s) or example(s). In addition, the specific features, structures, materials or characteristics may be included in any one or more embodiments or examples in any suitable manner.

Hereinafter, the terms “first” and “second” are only used for descriptive purposes, and are not to be construed as indicating or implying relative importance or implicitly indicating the number of indicated technical features. Thus, a feature defined by “first” or “second” may explicitly or implicitly includes one or more of the features. In the description of the embodiments of the present disclosure, the term “a plurality of” or “the plurality of” means two or more unless otherwise specified.

The term “approximately” as used herein includes a stated value and an average value within an acceptable deviation range of a particular value, the acceptable deviation range is determined by a person of ordinary skill in the art, in consideration of measurement in question and errors associated with the measurement of a particular quantity (i.e., limitations of a measurement system).

In the related art, an OLED display panel includes a base and a plurality of sub-pixels disposed on the base. Each sub-pixel includes a pixel circuit, an anode, a light-emitting layer, and a cathode that are sequentially disposed on the base, and cathodes of the plurality of sub-pixels are connected with each other to form a layer covering a whole surface. For a top-emission OLED display panel, light emitted by the light-emitting layer exits from the cathode, and the cathode needs to be set as a transparent or translucent conductive film. Therefore, a film thickness of the cathode needs to be thin, which causes resistance of the cathode to be high, and a voltage drop, i.e., an IR drop, when a cathode voltage signal is transmitted in the whole cathode layer to be large.

In order to reduce the voltage drop of cathode signal during transmission, auxiliary electrode(s) may be arranged in the display panel. The auxiliary electrode is a metal wire or a metal mesh. The cathodes of the plurality of sub-pixels and the auxiliary electrode(s) are connected in parallel, and the IR-Drop may be reduced. An arrangement manner is to provide an auxiliary electrode between the anode and the base, and provide a contact hole in an insulating layer between the auxiliary electrode and the cathode, so that the cathode is electrically connected to the auxiliary electrode through the contact hole.

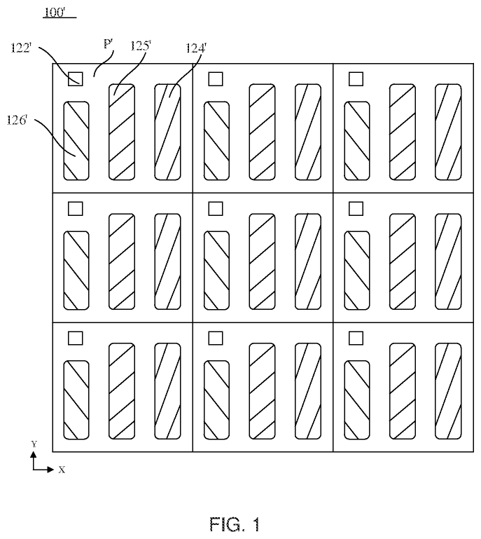

As shown in FIG. 1, the display substrate 100′ has a plurality of pixel regions P′, and each pixel region P′ has a blue sub-pixel 124′, a green sub-pixel 125′, and a red sub-pixel 126′. In a column direction Y in which the plurality of pixel regions P′ are arranged, a contact hole 122′ for electrically connecting the cathode of the sub-pixel and the auxiliary electrode is disposed between two adjacent red sub-pixels 126′. The display substrate 100′ is provided with an accommodating layer, the accommodating layer has a plurality of depressions, and light-emitting layer of each sub-pixel is disposed in a depression. The contact hole 122′ penetrates the accommodating layer.

For a display substrate using a printing process to fabricate the light-emitting layer, a sufficiently long distance is required between the contact hole 122′ and an adjacent red sub-pixel 126′, so as to avoid poor contact between the cathode and the auxiliary electrode caused by the overflow of ink into the contact hole 122′ when the light-emitting layer is printed in the depression. However, this leads to a decrease in an aperture ratio of the display substrate 100′ to decrease, thereby affecting a display effect of the display substrate 100′.

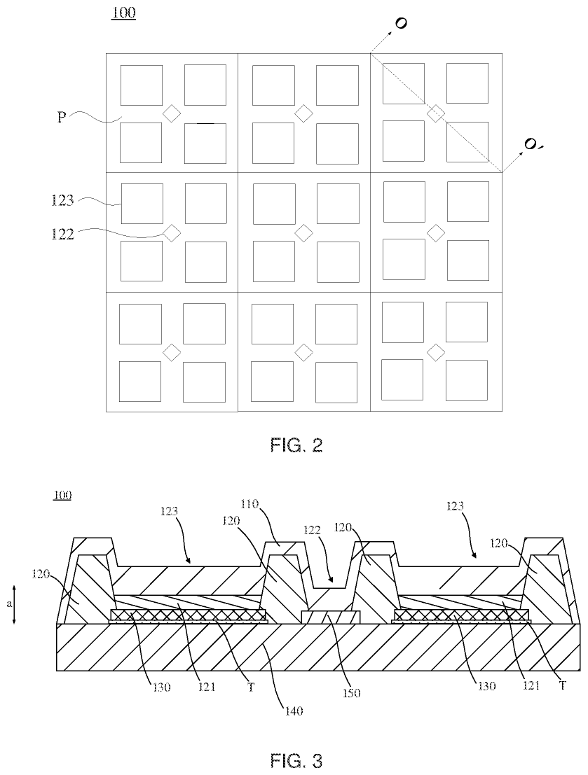

Some embodiments of the present disclosure provide a display substrate. As shown in FIGS. 2 to 4, the display substrate 100 has a plurality of pixel regions P. It will be noted that, in this text, the “pixel region P” refers to a region in which a pixel in the display substrate 100 is located. A pixel is a minimum sub-pixel repeating unit group formed by a plurality of sub-pixels. That is, the display substrate 100 includes a plurality of pixels, each pixel includes a plurality of sub-pixels, and number, size, color, and arrangement of the sub-pixels included in each pixel are the same. For example, each pixel includes a red sub-pixel, a green sub-pixel, and a blue sub-pixel. Sub-pixels with a same color in each pixel have a same size, and the arrangements of the plurality of sub-pixels in each pixel are the same. Therefore, the red sub-pixel, the green sub-pixel and the blue sub-pixel may form a minimum sub-pixel repeating unit group, and a region in which the minimum sub-pixel repeating unit group is located is the pixel region P.

The display substrate 100 includes a base 140 and an accommodating layer 120 disposed on the base 140. A portion of the accommodating layer 120 located in each pixel region P is provided with a contact hole 122 and a plurality of depressions 123. The plurality of depressions 123 are located on a periphery of the contact hole 122, and each depression 123 is spaced apart from the contact hole 122. In a direction (a) perpendicular to the base, the plurality of depressions 123 and the contact hole 122 penetrate the accommodating layer 120.

The display substrate 100 further includes a light-emitting layer 121 disposed in each depression 123. By using an ink-jet printing (IJP) process, ink of light-emitting material is printed into the depression 123, and the light-emitting layer 121 is formed after the ink is dried.

The display substrate 100 further includes an electrical connection structure disposed on the base 140, and a portion of the electrical connection structure passes through the contact hole 122.

For example, the electrical connection structure includes at least one auxiliary electrode 150 disposed between the base 140 and the accommodating layer 120, and a cathode layer 110 disposed on a side of the accommodating layer 120 and the light-emitting layer 121 away from the base 140. The at least one auxiliary electrode 150 is located on a side of the contact hole 122 proximate to the base 140. At least one portion of the cathode layer 110 is located in the contact hole 122, so that the cathode layer 110 and the at least one auxiliary electrode 150 are electrically connected through the contact hole 122.

For example, the cathode layer 110 may be fabricated by using an evaporation process. A material of the cathode layer 110 may include metal, transparent conductive oxide (TCO), or a combination of the two.

The cathode layer 110 and the at least one auxiliary electrode 150 are electrically connected, impedance of the cathode layer 110 may be reduced, thereby avoiding a large voltage drop (i.e., IR-Drop) generated by current flowing through the cathode layer 110.

The display substrate 100 further includes an anode 130 disposed between the base 140 and the light-emitting layer 121, and a pixel circuit T disposed between the anode 130 and the base 140. The pixel circuit T is electrically connected to the anode 130.

A voltage signal is transmitted to the anode 130 through the pixel circuit T, and an electric field is formed between the anode 130 and the cathode layer 110 with a voltage, thereby exciting the light-emitting layer 121 located between the anode 130 and the cathode layer 110 to emit light.

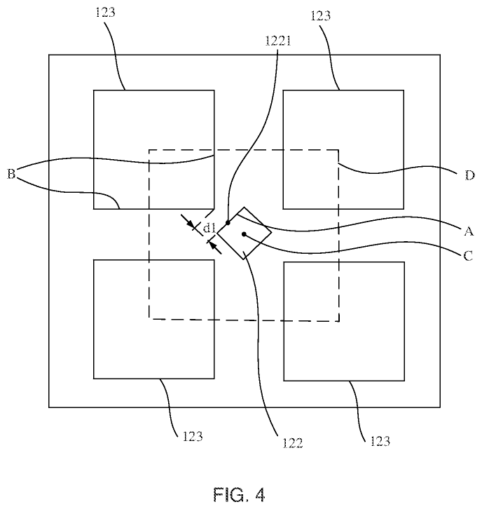

As shown in FIG. 4, in position points of a side of an orthogonal projection of the contact hole 122 on the base 140, a position point with a shortest distance from a wall of at least one depression 123 located on the periphery of the contact hole 122 is a first position point 1221. That is, a minimum distance between the first position point 1221 and the wall of the at least one depression 123 is a first distance d1, and a minimum distance between other position points of the contact hole 122 and the wall of the at least one depression 123 is a second distance. The first distance d1 is always less than the second distance. In addition, an orthogonal projection of the contact hole 122 on the base 140 and orthogonal projections of the plurality of depressions 123 on the base 140 are in a shape of polygon or approximate polygon, the first position point 1221 is not located at a corner of the polygonal or the approximate polygonal orthogonal projection of the contact hole on the base, and a side A of the orthogonal projection of the contact hole 122 on the base closest to the depression 123 is not parallel to at least one side B of the orthogonal projection of the depression 123 proximate to the contact hole 122.

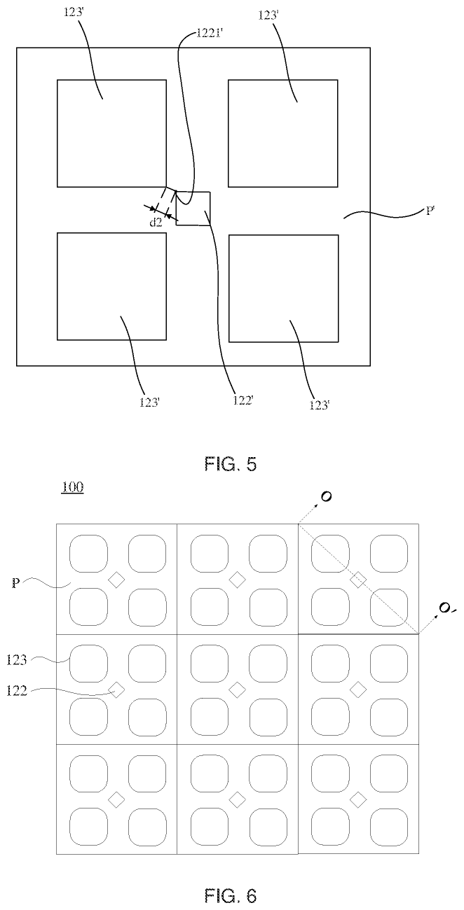

In the related art, as shown in FIG. 5, another distribution diagram of depressions 123′ and a contact hole 122′ that are in an accommodating layer is provided. In position points of a side of an orthogonal projection of the contact hole 122′ on the base, a distance between a second position point 1221′ and a wall of at least one depression 123′ located on a periphery of the contact hole 122′ is shortest, and the minimum distance is d2. An area of an orthogonal projection of the depression 123′ on the base, i.e., an opening area of the depression 123′ is the same as an opening area of the depression 123 in the embodiments of the present disclosure, an area of an orthogonal projection of the contact hole 122′ on the base, i.e., an opening area of the contact hole 122′ is the same as an opening area of the contact hole 122 in the embodiments of the present disclosure, and a distance between a center of the depression 123′ and a center of the contact hole 122′ is the same as a distance between a center of the depression 123 and a center of the contact hole 122 in the embodiments of the present disclosure. In this case, the first distance d1 in the embodiments of the present disclosure is greater than the minimum distance d2.

In the embodiments of the present disclosure, a relative position relationship between the depression 123 and the contact hole 122 may be changed, that is, the orthogonal projection of the contact hole 122 on the base 140 is in the shape of polygon or approximate polygon, the first position point is not located at the corner of the polygonal or the approximate polygonal orthogonal projection of the contact hole on the base, and the side A of the orthogonal projection of the contact hole 122 on the base closest to the depression 123 is not parallel to the at least one side B of the orthogonal projection of the depression 123 proximate to the contact hole 122. In this way, in a case where the distance between the center of the depression 123 and the center of the contact hole 122 remains unchanged relative to the related art, the minimum distance between the depression 123 and the contact hole 122 may be increased, that is, the first distance d1 may be increased, so as to avoid poor contact between the cathode layer 110 and the auxiliary electrode 150 caused by the overflow of the ink into the contact hole 122 when the light-emitting layer 121 is printed in the depression 123. In addition, under a premise of ensuring that the ink does not overflow into the contact hole 122 when the light-emitting layer 121 is printed, the opening area of the depression 123 may be appropriately increased, thereby increasing the aperture ratio of the display substrate 100 and improving the display effect of the display panel.

In some embodiments, as shown in FIG. 4, a side of the orthogonal projection of the contact hole 122 on the base 140 is directly opposite to a corner of an orthogonal projection of a depression 123 located on the periphery of the contact hole 122 on the base 140, and the first position point 1221 is located on this side.

Referring to FIG. 5, in the related art, the orthogonal projection of the contact hole 122′ on the base 140 is a polygon, and a corner of the polygon is directly opposite to a corner of the orthogonal projection of the depression 123′ located on the periphery of the contact hole 122′ on the base 140, so that the second position point 1221′ is located at the corner of the polygon. In the embodiments of the present disclosure, in a case where, relative to the related art, the opening areas of the depression 123 and the contact hole 122 remain unchanged, and the distance between the center of the depression 123 and the center of the contact hole 122 remains unchanged, the side of the orthogonal projection of the contact hole 122 on the base 140 is directly opposite to the corner of the orthogonal projection of the depression 123 located on the periphery of the contact hole 122 on the base 140, and the first position point 1221 is located on this side, the minimum distance between the depression 123 and the contact hole 122 may be increased, thereby avoiding poor contact between the cathode layer 110 and the auxiliary electrode 150 caused by the overflow of the ink into the contact hole 122 when the light-emitting layer 121 is printed in the depression 123.

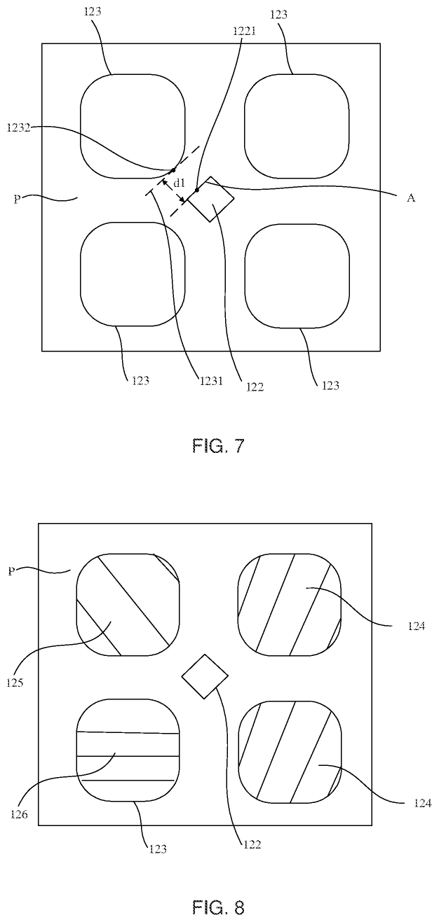

In some embodiments, as shown in FIGS. 6 and 7, corners of the orthogonal projection of the depression 123 on the base 140 are rounded corners, which is beneficial to improve a drying uniformity of the ink used for printing the light-emitting layer 121.

On this basis, in the orthogonal projections of the contact hole 122 and the depression 123 directly opposite the contact hole 122 on the base 140, a tangent line 1231 at a bisecting point 1232 of the rounded corner, directly opposite to the contact hole 122, of the depression 123 is parallel to the side A, directly opposite to the depression 123, of the contact hole 122. In this case, the first distance d1 is the distance between the tangent line 1231 and the side A of the contact hole 122 directly opposite to the depression 123.

Through the above arrangement manner, the minimum distance between the first position point 1221 and the wall surface of the depression 123 may be further increased, that is, the first distance d1 may be increased.

In some embodiments, as shown in FIGS. 4 and 7, in the pixel region P, in the orthogonal projections of the contact hole 122 and the plurality of depressions 123 on the base 140, sides of the contact hole 122 are directly opposite to corners of the plurality of depressions 123 located on the periphery of the contact hole 122.

Through the above arrangement manner, the plurality of depressions 123 are distributed around the contact hole 122, so that the arrangement of the depressions 123 and the contact hole 122 in the accommodating layer 120 may be more compact. In a case where an area of the base occupied by the accommodating layer 120 remains unchanged, a number of the depressions 123 disposed in the accommodating layer 120 may be increased in the above arrangement manner, which is beneficial to increase the aperture ratio of the display substrate 100.

In some embodiments, as shown in FIGS. 4 and 7, the orthogonal projection of the contact hole 122 on the base 140 is in the shape of rectangle. Four depressions 123 are disposed in the pixel region P, and four sides of the rectangular orthogonal projection of the contact hole 122 are directly opposite to the corners of the four depressions 123 located on the periphery of the contact hole 122.

For example, the contact hole 122 is located at a center position C of a rectangle D formed by sequentially connecting centers of the four depressions 123.

In some embodiments, the areas of the orthogonal projections of the four depressions 123 on the base 140 are same. That is, the opening areas of the four depressions 123 are same. After the ink of the light-emitting material is printed into the depressions 123, since the opening areas of the four depressions 123 are the same, exposed areas of the ink of the light-emitting materials in the four depressions 123 are the same. In a same dry environment, time for the ink of the light-emitting material to dry and form a film is approximately the same, which is beneficial to improve the thickness uniformity of the formed light-emitting layer 121.

In the related art, compared with ink materials used in light-emitting layers that emit red light and green light, an ink material used in a light-emitting layer that emits blue light has a shorter service life. As shown in FIG. 1, the numbers of the blue sub-pixels 124′, the green sub-pixels 125′ and the red sub-pixels 126′ in each pixel region 101 are the same. Moreover, areas of the blue sub-pixel 124′ and the green sub-pixel 125′ are the same. In order to stagger the contact hole 122 and provide a space for the contact hole 122, the area of the red sub-pixel 126′ is slightly less than the area of the blue sub-pixel 124′ or the green sub-pixel 125′. However, a difference between the area of the blue sub-pixel 124′ and the area of the red sub-pixel 126′ is not sufficient to eliminate a problem of color shift generated in a display image of the display panel caused by a difference of the service life of the ink materials of the two.

In order to solve the above problem, in some embodiments, as shown in FIG. 8, in a case where four depressions 123 are disposed in the pixel region P, light-emitting layers 121 disposed in two depressions 123 are light-emitting layers capable of emitting blue light (see the blue sub-pixel 124 in FIG. 8), and light-emitting layers 121 disposed in remaining two depressions 123 are a light-emitting layer capable of emitting red light (see the red sub-pixel 126 in FIG. 8) and a light-emitting layer 121 capable of emitting green light (see the green sub-pixel 125 in FIG. 8).

Referring to the pixel distributions in FIGS. 1 and 8, the service life of sub-pixels of different colors in a pixel region P is tested, and the test result obtained is in Table 1 below:

TABLE 1

| Service life | Red sub-pixel | Green sub-pixel | Blue sub-pixel |
|---|---|---|---|
| The related art | 12 | 6 | 1 |
| Embodiments | 5.1 | 1.7 | 1 |
| of the present | | | |
| disclosure | | | |

In the above table, the service life of the blue sub-pixel is taken as one unit.

It can be seen from the above table that, in the related art, a ratio of the service life of the red sub-pixel 126′ to the blue sub-pixel 124′ is up to 12. In the embodiments of the present disclosure, the number of the blue sub-pixels 124 is increased (the number of the depressions 123 provided with the light-emitting layer 121 capable of emitting blue light needs to be increased), a total area of the blue sub-pixels 124 in the pixel region P is increased. In a case where the areas of the red sub-pixel 126′, the green sub-pixel 125 and the blue sub-pixel 124′ are the same, the total area of the blue sub-pixels 124 in the pixel region P is twice the area of the red sub-pixels 126 or the green sub-pixels 125. Therefore, a difference in attenuation speed between the blue sub-pixel 124 and the red sub-pixel 126 or the green sub-pixel 125 in the pixel region P may be reduced, so that the ratio of the service life of the red sub-pixel 126 to the blue sub-pixel 124 is reduced to 5.1. The service life of the blue sub-pixel 124 in the pixel region P may be increased, and the problem of color shift generated in the display panel caused by the large difference in the attenuation speed of the sub-pixels may be improved.

In addition, referring to FIGS. 1 and 6, in a case where the size of the pixel region P is 157 μm×157 μm, a comprehensive aperture ratio of the display substrate 100 is calculated, and is shown in Table 2 below.

TABLE 2

| | R | G | B | Comprehensive |
|---|---|---|---|---|
| | (area μm²) | (area μm²) | (area μm²) | aperture ratio |
| The related art | 3810.6 | 4771.9 | 4771.9 | 54.2% |
| Embodiments of | 3560.3 | 3560.3 | 7120.5 | 57.8% |
| the present | | | | |
| disclosure | | | | |

In the table, “R” refers to a total area of the red sub-pixels 126 in the pixel region P; “G” refers to a total area of the green sub-pixel 125 in the pixel region P; “B” refers to a total area of two blue sub-pixels 124 in the pixel region P; and the “comprehensive aperture ratio” refers to a ratio of the total area of the red sub-pixel 126, the green sub-pixel 125, and the two blue sub-pixels 124 in the pixel region P to the total area of the pixel region P.

It can be seen that, in the embodiments of the present disclosure, in a pixel region P, in the orthogonal projections of the contact hole 122 and the plurality of depressions 123 on the base 140, sides of the contact hole 122 are directly opposite to corners of the plurality of depressions 123 located on the periphery of the contact hole 122. That is, the plurality of depressions 123 are distributed around the contact hole 122. The comprehensive aperture ratio of the display substrate 100 may be increased in this arrangement manner, which is beneficial to improve the display quality of the display panel.

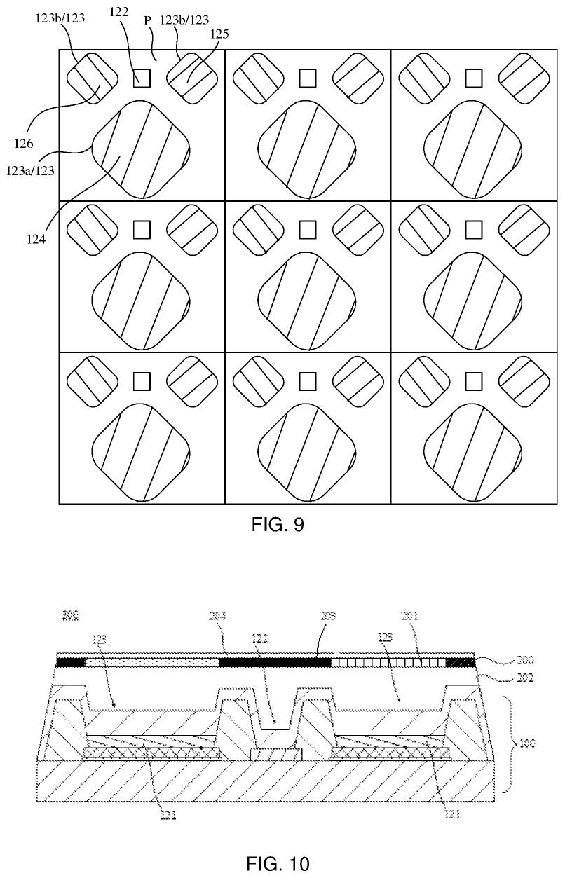

In some other embodiments, as shown in FIG. 9, three depressions 123 are disposed in the pixel region P, and three of the four sides of the rectangular orthogonal projection of the contact hole 122 are directly opposite to corners of the three depressions 123 located on the periphery of the contact hole 122.

For example, the three depressions 123 are disposed around the contact hole 122.

In some embodiments, as shown in FIG. 9, in a case where three depressions 123 are disposed in the pixel region P, one of the depressions 123 is a first depression 123a, and a light-emitting layer 121 disposed in the first depression 123a is a light-emitting layer 121 capable of emitting blue light. Remaining two depressions 123 are second depressions 123b, and light-emitting layers 121 disposed in the two second depressions 123b are a light-emitting layer 121 capable of emitting red light and a light-emitting layer 121 capable of emitting green light.

An area of an orthogonal projection of the first depression 123a on the base 140 is greater than an area of an orthogonal projection of each second depression 123b on the base 140.

Through the above arrangement manner, the difference in the attenuation speed between the blue sub-pixel 124 and the red sub-pixel 126 or the green sub-pixel 125 may be reduced, so that the service life of blue sub-pixel 124 may be improved.

In some embodiments, a ratio of the area of the orthogonal projection of the first depression 123a on the base 140 to the area of the orthogonal projection of each second depression 123b on the base 140 is greater than or equal to 1.5, and less than or equal to 6. That is, the ratio of the area of the blue sub-pixel 124 to the area of the red sub-pixel 126 and to the area of the green sub-pixel 125 is greater than or equal to 1.5, and less than or equal to 6. For example, the ratio is 1.5, 2, 2.5, 3, 5, or 6.

It is discovered by inventors through research that, in a case where the ratio of the area of the blue sub-pixel 124 to the area of the red sub-pixel 126 and to the area of the green sub-pixel 125 are within the above range, the attenuation speed of the blue sub-pixel 124 may be reduced, so that the service life of the blue sub-pixel 124 may be increased, thereby improving the color shift of the display panel.

Some embodiments of the present disclosure further provide a display panel 300, as shown in FIG. 10, including the display substrate 100 in any of the above embodiments, and a photoresist cover plate 200 stacked with the display substrate 100. The photoresist cover plate 200 includes a plurality of color filter photoresists 201, and each color filter photoresist 201 is opposite to one depression 123 of the display substrate 100. Light emitted by the display substrate 100 may be filtered by the color filter photoresist 201, so that the display panel 300 has a good light-emitting effect.

In some embodiments, in the plurality of depressions 123 in each pixel region P of the display substrate 100, light-emitting layers 121 disposed in at least two depressions 123 are light-emitting layers 121 capable of emitting blue light. The color filter photoresists 201 in the photoresist cover plate 200 opposite to the light-emitting layers 121 capable of emitting blue light are blue photoresists, and blue light that is transmitted by the blue photoresists corresponding to different light-emitting layers 121 capable of emitting blue light in the same pixel region P have different wavelength ranges, or have different spectrum peaks.

For example, the light-emitting layers 121 disposed in the two depressions 123 are light-emitting layers 121 capable of emitting blue light, and a blue photoresist corresponding to one of the light-emitting layers 121 capable of emitting blue light is a first blue photoresist, and another blue photoresist corresponding to another light-emitting layer 121 capable of emitting blue light is a second blue photoresist. A wavelength range of the blue light that is transmitted by the first blue photoresist is different from a wavelength range of the blue light that is transmitted by the second blue photoresist, so that the blue sub-pixel corresponding to the first blue photoresist displays light blue, and the blue sub-pixel corresponding to the second blue photoresist displays dark blue.

Alternatively, a spectrums peak of the blue light that is transmitted by the first blue photoresist is different from a spectrums peak of the blue light that is transmitted by the second blue photoresist. For example, one of the peaks is 430 nm and another peak is 460 nm, so that one of the blue sub-pixels corresponding to the first blue photoresist and the second blue photoresist displays light blue, and another displays dark blue. It will be noted that, in the foregoing case, the wavelength range of the blue light that is transmitted by the first blue photoresist and the wavelength range of the blue light that is transmitted by the second blue photoresist may be the same.

Through the above arrangement manner, the blue lights emitted by at least two blue sub-pixels in the display substrate 100 appear as blue lights with different shades after passing through corresponding blue photoresists, for example, dark blue light and light blue light, so that the color gamut of the display image of the display panel 300 may be increased. In addition, according to the requirements of the color gamut of the display image, blue light with a certain shade may be selected. That is, a blue sub-pixel corresponding to a corresponding blue photoresist is turned on, and another blue sub-pixel is turned off. In this way, the power consumption of the display panel 300 may be reduced.

In some embodiments, as shown in FIG. 10, the photoresist cover plate 200 further includes a black matrix 203, and the plurality of color filter photoresists 201 are separated by the black matrix 203 to prevent cross-color between sub-pixels of different colors.

In some embodiments, the photoresist cover plate 200 further includes a base substrate 204, and the plurality of color filter photoresists 201 and the black matrix 203 are disposed on the base substrate 204.

In a manufacturing process of the display panel 300, the black matrix 203 may be formed on a side of the base substrate 204 first, and then the plurality of color filter photoresists 201 may be formed, and then the manufactured photoresist cover plate 200 and the manufactured display substrate 100 are superimposed together to form the display panel 300.

In some embodiments, as shown in FIG. 10, the display panel 300 further includes an encapsulating film 202 disposed between the display substrate 100 and the photoresist cover plate 200. The encapsulating film 202 includes at least an inorganic encapsulating film.

For example, for the fabrication of the inorganic encapsulating film, a chemical vapor deposition (CVD) method may be used for forming the inorganic encapsulating film, so that the inorganic encapsulating film may be covered on the display substrate 100 to protect the display substrate 100. A material of the inorganic encapsulating film may include silicon nitride (SiNₓ), silicon oxynitride (SiONₓ), etc., and its thickness may be in a range of 0.3 μm to 1 μm, such as 0.3 μm, 0.5 μm, 0.8 μm, or 1 μm.

The encapsulating film 202 may further includes an organic encapsulating film stacked with the inorganic encapsulating film. In a case where the encapsulating film 202 includes both the inorganic encapsulating film and the organic encapsulating film, in a direction perpendicular to a display surface of the display panel 300, the encapsulating film 202 includes an inorganic package film, an organic package film, and an inorganic package film in sequence.

Some embodiments of the present disclosure further provide a display apparatus 400, which includes the display panel 300 in the above embodiments.

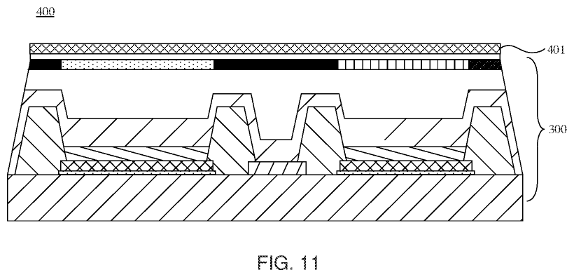

As shown in FIG. 11, the display apparatus 400 may be an electroluminescence display apparatus, and the electroluminescence display apparatus includes a display panel 300 and a polarizer 401 pasted on the display panel 300. The use of the polarizer 401 can reduce reflection of natural light by a reflective structure (such as an anode, a thin film transistor, a metal signal line, etc.) in the display apparatus 400, thereby avoiding interference of the reflection of the natural light on the display effect of the display apparatus 400.

The above-mentioned display apparatus 400 may be any device that can display images whether in motion (e.g., a video) or stationary (e.g., a still image), and regardless of text or image. More specifically, it is contemplated that the described embodiments may be implemented in or associated with a variety of electronic devices. The variety of electronic devices may include (but not limit to), for example, a mobile phone, a wireless device, a personal data assistant (PAD), a hand-held or portable computer, a global positioning system (GPS) receiver/navigator, a camera, a MPEG-4 Part 14 (MP4) video player, a video camera, a game console, a watch, a clock, a calculator, a TV monitor, a flat-panel display, a computer monitor, a car display (such as an odometer display), a navigator, a cockpit controller and/or display, a camera view display (such as a rear view camera display in a vehicle), an electronic photo, an electronic billboard or sign, a projector, a building structure, and a packaging and an aesthetic structure (such as a display for an image of a piece of jewelry), etc.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display substrate having a plurality of pixel regions; the display substrate comprising:
a base;
an accommodating layer disposed on the base; the accommodating layer being provided with a contact hole and a plurality of depressions that are located in a pixel region, the plurality of depressions being located on a periphery of the contact hole, and each depression being spaced apart from the contact hole; in a direction perpendicular to the base, the plurality of depressions and the contact hole penetrating the accommodating layer;
an electrical connection structure disposed on the base, and a portion of the electrical connection structure passing through the contact hole; and
a light-emitting layer disposed in each depression; wherein
in position points of a side of an orthogonal projection of the contact hole on the base, a position point with a shortest distance from a wall of at least one depression located on the periphery of the contact hole is a first position point; an orthogonal projection of the contact hole on the base and orthogonal projections of the plurality of depressions on the base are in a shape of approximate polygon, the first position point is not located at a corner of the approximate polygonal orthogonal projection of the contact hole on the base, and a side of the orthogonal projection of the contact hole on the base closest to the depression is not parallel to at least one side(s) of the orthogonal projection of the depression on the base proximate to the contact hole.

2. The display substrate according to claim 1, wherein a side of the orthogonal projection of the contact hole on the base is directly opposite to a corner of an orthogonal projection of a depression located on the periphery of the contact hole on the base, and the first position point is located on this side.

3. The display substrate according to claim 2, wherein corners of the orthogonal projection of the depression on the base are rounded corners; and
in orthogonal projections of the contact hole and the depression directly opposite to the contact hole on the base, a tangent line at a bisecting point of a rounded corner, directly opposite to the contact hole, of the depression is parallel to a side, directly opposite to the depression, of the contact hole.

4. The display substrate according to claim 2, wherein in the pixel region, and in orthogonal projections of the contact hole and the plurality of depressions on the base, sides of the contact hole are directly opposite to corners of the plurality of depressions located on the periphery of the contact hole.

5. The display substrate according to claim 4, wherein the orthogonal projection of the contact hole on the base is in the shape of rectangle;
four depressions are disposed in the pixel region, and four sides of the rectangular orthogonal projection of the contact hole are directly opposite to corners of the four depressions located on the periphery of the contact hole; or
three depressions are disposed in the pixel region, and three of the four sides of the rectangular orthogonal projection of the contact hole are directly opposite to corners of the three depressions located on the periphery of the contact hole.

6. The display substrate according to claim 1, wherein four depressions are disposed in the pixel region; and light-emitting layers disposed in two depressions are light-emitting layers capable of emitting blue light, and light-emitting layers disposed in remaining two depressions are a light-emitting layer capable of emitting red light and a light-emitting layer capable of emitting green light.

7. The display substrate according to claim 6, wherein the contact hole is located at a center position of a rectangle formed by connecting centers of the four depressions in sequence.

8. The display substrate according to claim 6, wherein areas of orthogonal projections of the four depressions on the base are same.

9. The display substrate according to claim 1, wherein three depressions are disposed in the pixel region; one of the depressions is a first depression, and a light-emitting layer disposed in the first depression is a light-emitting layer capable of emitting blue light, remaining two depressions are second depressions, and light-emitting layers disposed in the two second depressions are a light-emitting layer capable of emitting red light and a light-emitting layer capable of emitting green light; and
an area of an orthogonal projection of the first depression on the base is greater than an area of an orthogonal projection of each second depression on the base.

10. The display substrate according to claim 9, wherein the three depressions are disposed around the contact hole.

11. The display substrate according to claim 9, wherein a ratio of the area of the orthogonal projection of the first depression on the base to the area of the orthogonal projection of each second depression on the base is greater than or equal to 1.5, and less than or equal to 6.

12. The display substrate according to claim 1, wherein the electrical connection structure includes:
at least one auxiliary electrode disposed between the base and the accommodating layer, and the at least one auxiliary electrode being located on a side of the contact hole proximate to the base; and
a cathode layer disposed on a side of the accommodating layer and the light-emitting layer away from the base, and at least one portion of the cathode layer being located in the contact hole, so that the cathode layer and the at least one auxiliary electrode(s) are electrically connected through the contact hole.

13. The display substrate according to claim 12, further comprising:
an anode disposed between the base and each light-emitting layer; and
a pixel circuit disposed between the anode and the base, and the pixel circuit being electrically connected to the anode.

14. A display panel, comprising:
the display substrate according to claim 1; and
a photoresist cover plate stacked with the display substrate, the photoresist cover plate including a plurality of color filter photoresists, and each color filter photoresist being opposite to one depression of the display substrate.

15. The display panel according to claim 14, wherein in the plurality of depressions in each pixel region of the display substrate, light-emitting layers disposed in at least two depressions are light-emitting layers capable of emitting blue light; and
color filter photoresists in the photoresist cover plate opposite to the light-emitting layers capable of emitting the blue light are blue photoresists, and blue light that is transmitted by the blue photoresists corresponding to different light-emitting layers capable of emitting the blue light in a same pixel region have different wavelength ranges, or have different spectrums peaks.

16. A display apparatus, comprising the display panel according to claim 14.

17. A display apparatus, comprising the display panel according to claim 15.

18. The display substrate according to claim 3, wherein in the pixel region, and in orthogonal projections of the contact hole and the plurality of depressions on the base, sides of the contact hole are directly opposite to corners of the plurality of depressions located on the periphery of the contact hole.

19. The display substrate according to claim 7, wherein areas of orthogonal projections of the four depressions on the base are same.

20. The display substrate according to claim 10, wherein a ratio of the area of the orthogonal projection of the first depression on the base to the area of the orthogonal projection of each second depression on the base is greater than or equal to 1.5, and less than or equal to 6.
